(19) United States
(12) Patent Application Publication
(10) Pub. No.: US 2005/0273683 A1
(43) Pub. Date: Dec. 8, 2005

(54) Insertion of embedded test in RTL to GDSII flow

(75) Inventors: Jean-Francois Cote, Chelsea (CA); Benoit Nadeau-Dostie, Gatineau (CA); Fadi Maamari, San Jose, CA (US)

Correspondence Address: LOGICVISION (CANADA), INC., 1565 CARLING AVENUE, SUITE 508, OTTAWA, ON, K1Z 8R1, CA

(73) Assignee: LogicVision, Inc., San Jose, CA (US)

(21) Appl. No.: 11/144,764

(22) Filed: Jun. 6, 2005

Related U.S. Application Data
(60) Provisional application No. 60/577,171, filed on Jun. 7, 2004.

(51) Int. Cl. G01R 31/28; G06F 17/50

(52) U.S. Cl. 714/726; 716/4; 716/18

(57) ABSTRACT

A method of designing a scan testable integrated circuit with embedded test objects for use in scan testing the circuit, comprises compiling a register-transfer level (RTL) circuit description of the circuit into an unmapped circuit description; extracting information from the unmapped circuit description for use in generating and inserting RTL descriptions of test objects into the RTL circuit description and for use in generating and inserting scan chains into the circuit; generating and inserting the RTL descriptions of the test objects into the RTL circuit description to produce a modified RTL circuit description; storing the modified RTL circuit description; synthesizing the modified RTL description into a gate level circuit description of the circuit; and constructing and inserting scan chains into the gate level circuit description according to information extracted from the unmapped circuit description.

### CROSS-REFERENCE TO RELATED APPLICATIONS

This application claims the benefit of U.S. Provisional Patent Application Ser. No. 60/577,171 filed Jun. 7, 2004, incorporated herein by reference.

### BACKGROUND OF THE INVENTION

1. Field of the Invention

The present invention generally relates to designing of integrated circuits (“IC” or “chip”) and, more specifically, to a method and program product for implementing scan-test objects into a register-transfer level (RTL) circuit description of integrated circuits and extracting additional information useful in implementing scan chains and, optionally, test points in a gate-level description.

2. Description of Related Art

In the design of integrated circuits, it is commonplace for circuit designers to develop a RTL description of the circuit. To provide for scan testing of the circuit, test structures and scan chains are typically inserted into the circuit after the RTL circuit description has been synthesized into a gate level description using a technology library.

It would be desirable to insert scan related structures at RTL to accelerate the implementation of a scan-based test (ATPG or BIST) and improve the compatibility of the implementation process with the physical design tools which minimize, if not eliminate, access to a gate level circuit description derived from the RTL. These tools are often referred to as RTL-to-GDSII physical design tools. GDSII, which stands for “Graphic Design System II”, is a binary file format, classified as a “data interchange format”, used for transferring mask-design data between an IC designer and a fabrication facility (“Fab”). At the Fab, the GDSII data is converted into a machine-readable language called CATS (for Computer Aided Transcription Software) which transcribes the data so that it can be read by photomask systems used in the manufacture of semiconductors.

Heretofore, the gate level circuit description has been used by test tools to perform tasks such as checking design rules and inserting and partitioning scan chains. For circuits implementing embedded test or BIST circuits, separate pieces of RTL circuit description, are synthesized in a separate step and added to the gate level circuit description.

It is well known that significantly less time and computer memory are necessary to analyze RTL descriptions than gate-level descriptions because RTL descriptions abstract many details that are not relevant to the type of analysis needed for embedded test circuit insertion. A circuit designer can debug design rules faster and/or perform trade-off analyses (e.g. number of scan chains vs. length of scan chains) much faster using the RTL description.

Wang et al. United States Published Application No. U.S. 2003/0023941 A1 proposes inserting all test circuitry, including test controllers and scan chains, into the RTL description. The insertion of test controllers is desirable because it provides a complete RTL description for physical design tools. Insertion of test controller RTL into the original RTL description is acceptable because test controllers are localized circuits that have virtually no impact on the original RTL description. However, there are two major drawbacks to modification of the RTL description to describe scan chains. First, the scan chains descriptions have a dramatic impact on the RTL description because it affects most of the original RTL description. This makes it very difficult for the IC designer to debug. Second, the placement of scannable memory elements is fixed in position, precluding optimization scan chain ordering which is often used to reduce the area of scan-tested circuits.

There is a need for a circuit design method which overcomes the above discussed disadvantages of the prior art.

### SUMMARY OF THE INVENTION

The present invention seeks to provide a method and program product for quickly analyzing RTL circuit descriptions, incorporating into the RTL circuit description of test logic of objects necessary to implement a scan test and provide an RTL description of the test logic that is insensitive to the final implementation of the circuit by the physical design tool(s). In addition, the present invention provides information related to the connection of control signals of scan testable memory elements to physical design tools. The present invention modifies the original RTL circuit to include all scan ports to cores (or modules) whose footprint need to be preserved.

In general, the present invention is generally defined as a method of designing a scan testable integrated circuit with embedded test objects for use in scan testing the circuit, comprising: compiling a register-transfer level (RTL) circuit description of the circuit into an unmapped circuit description; extracting information from the unmapped circuit description for use in generating and inserting RTL descriptions of test objects into the RTL circuit description and for use in generating and inserting scan chains into the circuit; generating and inserting RTL descriptions of the test objects into the RTL circuit description to produce a modified RTL circuit description; storing the modified RTL circuit description; synthesizing the modified RTL description into a gate level circuit description of the circuit; and constructing and inserting scan chains into the gate level circuit description according to information extracted from the unmapped circuit description.

### BRIEF DESCRIPTION OF THE DRAWINGS

These and other features of the invention will become more apparent from the following description in which reference is made to the appended drawings in which:

FIG. 1 is a diagrammatic illustration of a simple integrated circuit defined by an RTL description of the circuit and showing cores with functional memory elements, with respective clocks, in the cores;

FIG. 2 is an illustration similar to FIG. 1, but illustrating scan insertion features, including various test objects, test ports, scan ports to be incorporated into the circuit, but not including scannable memory elements;

FIG. 3 is a flow diagram illustration a method according to an embodiment of the present invention; and

FIG. 4 is a block diagram of a program product according to an embodiment of the present invention; and

FIG. 5 and FIG. 6 illustrate alternative embodiments of incorporating scan chains and test points into gate level descriptions of an integrated circuit under design.

### DETAILED DESCRIPTION OF PREFERRED EMBODIMENTS

In the following detailed description, numerous specific details are set forth in order to provide a thorough understanding of the present invention, However, it will be understood by those skilled in the art that the present invention may be practiced without these specific details. In other instances, well known methods, procedures, components and circuits have not been described in detail so as not to obscure aspects of the present invention.

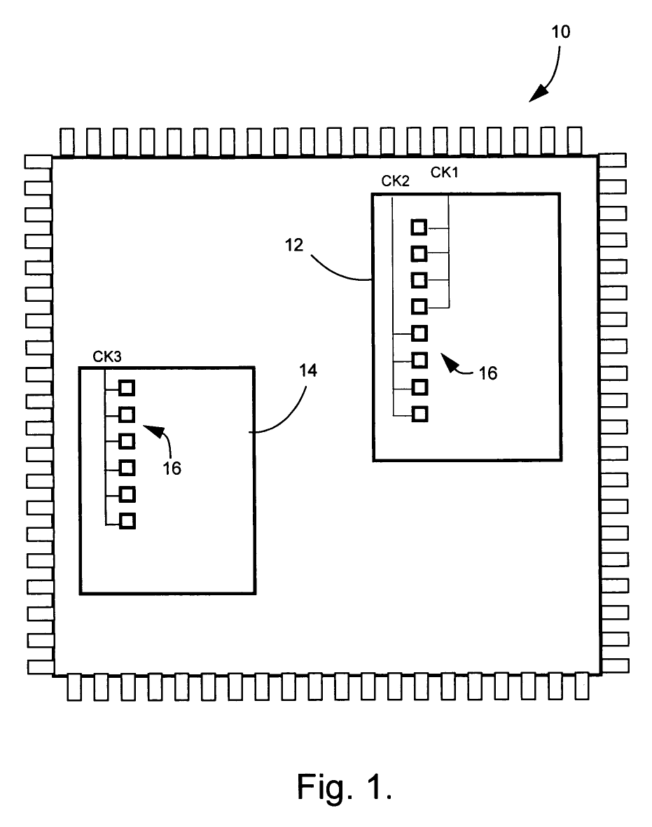

FIG. 1 diagrammatically illustrates a simple circuit 10 as developed by a circuit design engineer. The circuit has two cores 12 and 14, each having a plurality of functional memory elements 16 associated with respective clock domains. It is desired to insert test objects into the circuit RTL. Examples of test objects are an IEEE test access port (TAP), logic test controllers, memory test controllers, PLL BIST and the like. As compared to insertion of scan chains, the insertion of such test objects into the circuit RTL has little impact on the RTL circuit description. Generally, this simply involves inserting RTL descriptions of the test objects into the circuit RTL and connecting ports of the test objects to ports of the original circuit. It might also involve providing a selection mechanism to choose between a functional input or a test input provided by one of the test objects.

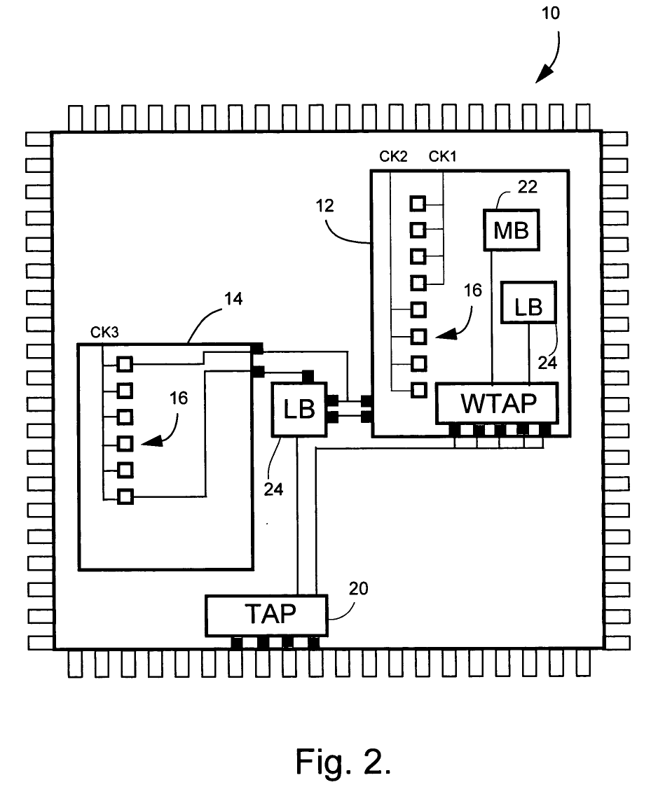

FIG. 2 illustrates the same circuit as FIG. 1, but includes a number of test objects. These include a Test Access Port (TAP) 20, memory test controllers 22, and logic test controllers 24. It will be understood by those skilled in the art that test objects include many other types of test objects such as, test controllers, including ATPG compressors and decompressors and BIST controllers, clock controllers and scan control signals generators, test points providing isolation from uncontrollable logic, test points providing isolation of modules to be tested independently from the rest of the circuit in an hierarchical scan test, test points which increase the testability of circuit nodes with low controllability and/or observability, scan control signals generators, including pipelining flip-flops.

The insertion of test circuitry also requires replacing functional memory elements with scannable memory elements and interconnecting the scannable memory elements to form scan chains which are used to load test stimuli into the memory elements and unload test responses, as is well known in the art. A scannable memory element includes a functional memory elements plus one or more multiplexers associated with the memory element, serial interconnection of the memory element with other scannable memory elements under control of control signals. It will be seen that substitution of scannable memory elements for functional memory elements at RTL would have a dramatic affect on the circuit RTL in that it would make the RTL description extremely difficult to debug and would prevent scan chain ordering which is used to reduce the area of scan-tested circuits.

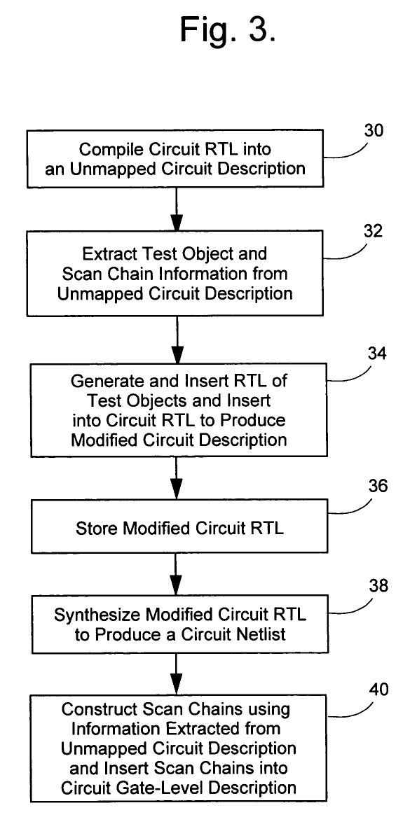

Applicants have found that these and other problems can be overcome by the embedded test insertion flow of the present invention, generally illustrated in FIG. 3. The method includes the steps of compiling a RTL circuit description of the circuit into a partially synthesized or unmapped circuit description (step 30); extracting information from the unmapped circuit description for use in generating and inserting RTL descriptions of test objects into the RTL circuit description and for use in generating and inserting scan chains into the circuit (step 32); generating and inserting the RTL descriptions of the test objects into the RTL circuit description to produce a modified RTL circuit description (step 34); storing the modified RTL circuit description (step 36); synthesizing the modified RTL description into a gate level circuit description of the circuit (step 38); and constructing and inserting scan chains into the gate level circuit description using information extracted from the unmapped circuit description (step 40) to produce a final circuit description.

The unmapped (or technology independent) circuit description will contain information required to embed test objects into the circuit RTL, including names and other details of cores, clock domains, ports, functional memory elements, and the like.

The unmapped description may be subjected to a scan design rules check. However, this check is optional. Skipping scan rules checking at this stage and assuming that rules will be checked later allows for generation of test controllers and quickly obtaining a gate count estimate and floorplan.

The unmapped description is analyzed to extract this information at step 32. The analysis is performed using user constraints or directives such as non-scannable memory elements, maximum number of chains, maximum scan chain length, cores, memory etc. The information is used by a software tool at step 34 to generate RTL descriptions of predetermined and/or desired test objects and associate test object port names with corresponding circuit port names in the test object insertion process. The information is also used to provide of scan ports for each of the cores to which scan chains will be connected in the scan chain insertion process at step 40. The test object insertion process results in a modified circuit RTL which will contain all test objects and cores with scan ports, but without scan chains or test points. It will be understood that test points of the type used for isolation, such as uncontrollable logic or core isolation in hierarchical case, will be inserted at RTL. Test Points related to circuit nodes with low controllability and/or observability are not inserted at RTL, but rather at the gate-level. This results in an RTL description which is very similar to the original RTL and, thus, which can be easily debugged if necessary. While scan chains and test points are not inserted at this stage, it is possible to specify scan chains configurations and store the configurations a scan chain specification for use at step 40.

The analysis of the partially synthesized description may include a number of steps including determining the location of test points; identifying and counting functional memory elements, including, optionally, test points, identifying the clock domain associated to each memory element; and, if the Applicants' Capture-by-Domain invention is employed (see U.S. Pat. No. 6,115,827 issued on Sep. 5, 2000 for “Clock Skew Management Method and Apparatus”), identifying source and destination memory elements of paths between clock domains if the Capture-by-Domain, and, associating each source and destination memory element, to a capture disable group; determining the number of scan chains based on the number of clock domains and user constraints; and assigning each memory element to a group of memory elements of the same domain to be connected in a chain.

The scan Chain Specification is generated to include for each group of memory elements, a group serial input port, a group serial output port, a list of memory elements, and, for each memory element, a serial input port; a serial output port; a scan enable port; a memory element type; and control signals including capture disable group for the Capture-by-Domain embodiment.

For each memory element type, an equation describing the connection of the serial input port; and an equation describing the connection of the scan enable port; and, for each a capture disable group, a combination of memory elements making the capture disable inactive are provided.

For each test point, if included, information is provided to guide the test point insertion process in the design tool, including controlability and observability values of signals that are identifiable in both the RTL and gate-level descriptions. The signals are inputs and output signals of the module or process containing the test point.

As indicated earlier, the modified RTL description is synthesized into a gate level circuit description, The gate-level circuit description is analyzed to ensure that all predetermined scan design rules are satisfied. Rules checking is done mostly to ensure that no errors were introduced during the synthesis and layout steps, due to ECO changes for example, and that the test objects are still consistent with the circuit.

The gate level circuit description is then modified by constructing and inserting scan chains between core scan ports using the scan chain configuration information contained in the scan chain specification, to produce a modified gate level circuit description (step 40). This step is performed by physical design tools using the scan chain specification.

Test Points

The present invention also provides for prediction of test points locations. The test points of concern at this stage relate to circuit nodes with low controllability and/or observability. Isolation test points are test objects which inserted in the RTL circuit description, as previously mentioned. The location of the test points provides for determining the number of additional memory elements that may be required in each clock domain. The test point memory elements are also described in the scan chain specification. The information is also used in the generation of the test logic. The test points can be predicted using controllability and observability measures such as those described in Applicant's U.S. Pat. No. 6,363,520 issued on Mar. 26, 2002 for “Method for Testability Analysis and Test Point Insertion at the RT-Level of a Hardware Development language (HDL) Specification” (Docket No. LVPAT010), incorporated herein by reference.

The test points are not inserted in the RTL description. Rather, the location of test points is calculated using a gate-level representation (mapped or unmapped), perhaps with information (controllability and observability measures) extracted at the RTL level (step 32).

As already mentioned, the present invention supports the advanced requirements such as Applicant's Capture-by-Domain invention of U.S. Pat. No. 6,115,827 issued on Sep. 5, 2000 for “Clock Skew Management Method and Apparatus” (Docket No. LVPAT008); the Multi-Cycle Path management invention of Applicant's U.S. Pat. No. 6,145,105 issued on Nov. 7, 2000 for “Method and Apparatus for Scan Testing Digital Circuits”, (Docket No. LVPAT002), and the shared isolation invention of Applicant's U.S. Pat. No. 6,615,392 issued on Sep. 2, 2003 for “Hierarchical Design and Test System, Program Product Embodying the Method, and Integrated Circuit Produced Thereby,” (Docket No. LVPAT020), all incorporated herein by reference.

The present invention further provides a program product which is stored on a computer readable storage medium on which is embedded one or more computer programs for designing a scan testable integrated circuit with embedded test objects for performing scan tests of the circuit. The one or more computer programs comprise a set of instructions for performing the above described method of the present invention.

In a preferred embodiment, the present invention provides a suite of software automation tools which inserts a set of embedded test objects into an integrated circuit for use in testing and diagnosing errors an IC. The tools include an embedded test creation tool which focuses on design predictability and ease-of-use combined with an increased level of test quality. The tool includes features, such as an top-down RTL rule checker which extracts design information from the RTL or netlist, and greatly improves embedded test insertion predictability.

The flow matches embedded test partitioning with the physical block partitioning of an IC. Heretofore, power, true at-speed testing, block speed binning forced a user to partition the embedded test logic differently from that of physical logic. Physical blocks that are large enough are best tested with a local logic test controller. This makes the test self-contained and simplifies the test interface at the block boundary. Smaller physical blocks can be tested by a top-level logic test controller.

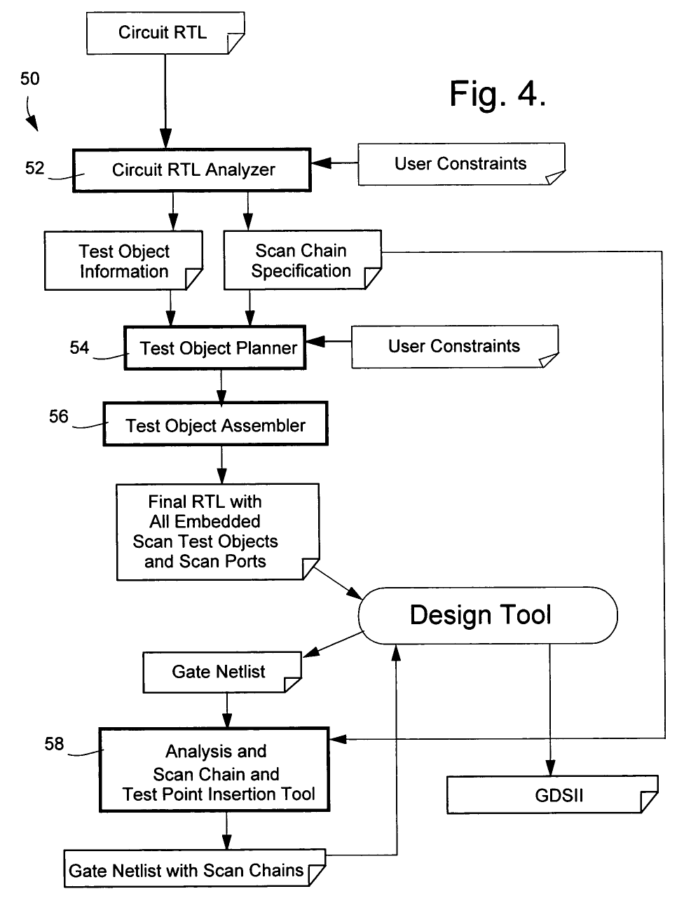

The automation tool 50 of the present invention comprises four major components which are utilized at different stages of an IC design flow. While the components are shown as separate elements, it will be understood that they may be combined in a single tool. The components are diagrammatically illustrated in FIG. 4.

Tool 52 determines whether a circuit design meets predetermined embedded test requirements, determines the location for test points and dedicated isolation cells in the circuit and extracts all pertinent design information from the RTL that will be required to generate to insert embedded test objects into the RTL circuit description and a scan chain specification. In order to extract the information, the tool compiles the circuit RTL into an unmapped circuit description, as described earlier.

Tool 54 plans the test object insertion process and generates a test object environment in which descriptions and details of the generated test objects will be stored.

Tool 56 performs the test object insertion process. In lower physical regions or cores of the circuit, the tool inserts embedded test controllers, such as TAPs, memory test controllers, and logic test controllers, creates scan ports on the block module, inserts RTL test points and any dedicated isolation cells determined by tool 52. At the chip top level, the tool inserts all top level embedded test objects, such as TAPs, boundary scan, logic test, and memory test, etc. into the circuit RTL and performs early verification of the embedded test objects in the design. The output of tool 56 is the aforementioned modified RTL circuit description which is synthesized into a gate level circuit in a subsequent step.

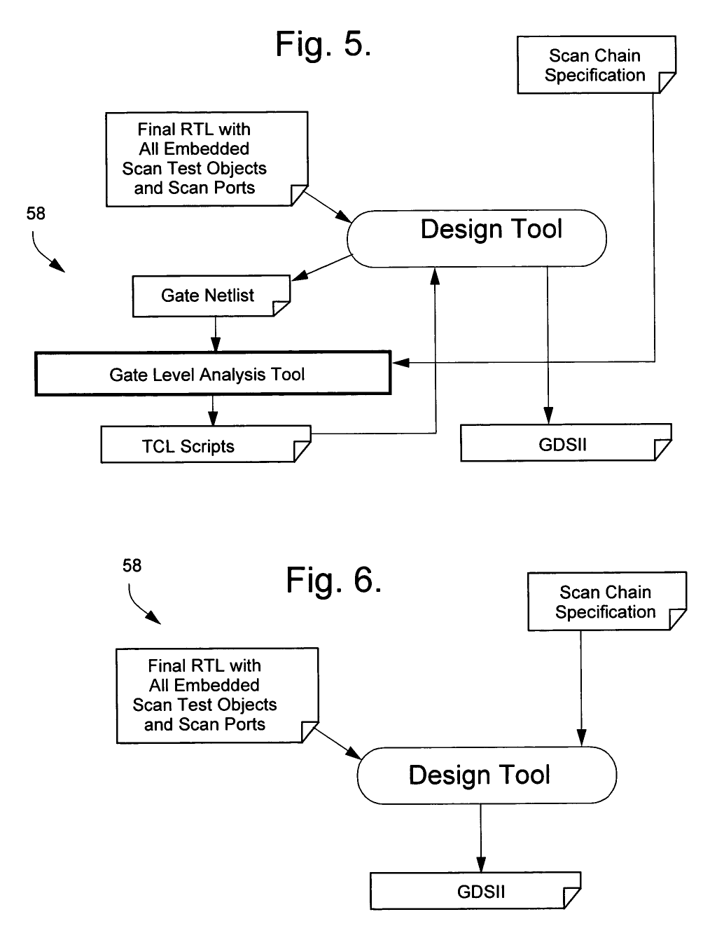

A scan chain insertion tool 58 generates and inserts scan chains and test points into the gate level description. There are generally three ways in which modify the gate-level circuit description can be modified. In all cases, the gate-level circuit description is modified at an early stage of optimization so that any potential impact of test points can be neutralized. Modification of a mapped netlist generated from the design tool will work best with design tools which provide a feature by which small changes, such as the insertion of test points, does not reduce significantly the ability of the design tool to perform optimization of the gate-level circuit. Modification of the mapped circuit description, via an API (Application Programming Interface), which performs the insertion directly in the design tool under the control of a series of commands (e.g. TCL scripts) that will take the scan chain specification as input. This approach preserves the ability of the design tool to perform optimization of the gate-level circuit. The scan chain specification can be generated entirely by the RTL analysis tool 52 or partially from tool 52 and tool 58 which extracts information from a gate-level netlist generated by the design tool. In one embodiment, shown in FIG. 4, scan insertion tool 58 uses the scan chain information and inserts scan chains and test points at the appropriate locations in the gate level circuit description produced by the design tool to produce a modified gate-level circuit description which replaces the original gate-level circuit description. In another embodiment, shown in FIG. 5, the tool uses the scan chain specification to generate Tool Command Language (TCL) scripts which are applied to the design tool to cause the design tool to insert the scan chains and test points into the gate-level circuit description. In still another embodiment, shown in FIG. 6, the scan chain specification is in a form which can be applied to the design tool to cause the tool to insert the scan chains and test points in the gate-level circuit description.

Tools 52, 54 and 56 operate at RTL while tools 58 operates at the gate-level, after the modified RTL circuit description has been synthesized into the gate-level circuit description.

Although the present invention has been described in detail with regard to preferred embodiments and drawings of the invention, it will be apparent to those skilled in the art that various adaptions, modifications and alterations may be accomplished without departing from the spirit and scope of the present invention. Accordingly, it is to be understood that the accompanying drawings as set forth hereinabove are not intended to limit the breadth of the present invention, which should be inferred only from the following claims and their appropriately construed legal equivalents.

1. A method of designing a scan testable integrated circuit with embedded test objects for use in scan testing said circuit, comprising:
compiling a register-transfer level (RTL) circuit description of said circuit into an unmapped circuit description;
extracting information from said unmapped circuit description for use in generating and inserting RTL descriptions of test objects into said RTL circuit description and for use in generating and inserting scan chains into said circuit;
generating and inserting said RTL descriptions of said test objects into said RTL circuit description to produce a modified RTL circuit description;
storing said modified RTL circuit description;
synthesizing said modified RTL description into a gate level circuit description of said circuit; and
constructing and inserting scan chains into said gate level circuit description according to information extracted from said unmapped circuit description.

2. A method as defined in claim 1, said constructing and inserting scan chains further including generating a final gate level circuit description.

3. A method as defined in claim 1, said constructing and inserting scan chains further including analyzing said gate level circuit description and said information for use in generating scan chains, generating Tool Command Language (TCL) scripts to cause a design tool to transform functional memory elements into scannable memory elements and generate a final gate level circuit description.

4. A method as defined in claim 1, said constructing and inserting scan chains further including analyzing said gate level circuit description and said information for use in generating scan chains, generating a modified gate level circuit description, and generating Tool Command Language (TCL) scripts to cause a design tool to substitute said modified gate level circuit description for said gate level circuit description.

5. A method as defined in claim 1, said generating and inserting said RTL descriptions including generating and inserting scan ports and test ports to modules whose footprint needs to be preserved.

6. A method as defined in claim 1, said information comprising clock domains in said circuit, identity and number of memory elements in each clock domain, interaction between memory elements of different clock domains, and controllability and observability of all nodes in the circuit.

7. A method as defined in claim 1, further including, verifying that said RTL circuit description satisfies predetermined scan design rules.

8. A method as defined in claim 1, said test objects including one or more of test controllers, clock controllers and test access ports, scan control signal generators.

9. A method as defined in claim 8, said test objects further including test points providing isolation from uncontrollable logic.

10. A method as defined in claim 8, said test objects further including test points providing isolation of modules to be tested independently of the rest of the circuit in a hierarchical scan test.

11. A method as defined in claim 8, said test objects further including test points increasing the testability of circuit nodes with low controllability and/or observability.

12. A method as defined in claim 8, said test controllers including ATPG compressors and decompressors and BIST controllers.

13. A method as defined in claim 1, further including generating a scan chain specification that describes scan chain requirements for said circuit from extracted information for use in generating and inserting scan chains into said circuit.

14. A method as defined in claim 1, said compiling a RTL circuit description of said circuit including partially synthesizing said RTL circuit description to generate said unmapped circuit description in which memory elements are inferred and distinguishable from combinational logic.

15. A method as defined in claim 1, said compiling a RTL circuit description of said circuit and said generating and inserting said RTL descriptions of test objects further including utilizing user specified constraints information including maximum number of scan chains and/or maximum scan chain length, frequency of clock domains, identification of non-scannable portions of the circuit, and identification of cores in a hierarchical test approach.

16. A method as defined in claim 1, said extracting information further including one or more of determining the location of test points, identifying and counting memory elements, identifying the clock domain associated with each memory element; and identifying source and destination memory elements of paths between clock domains.

17. A method as defined in claim 16, further including associating each source and destination memory element with a respective capture disable group.

18. A method as defined in claim 16, said extracting information further including determining the number of scan chains based on the number of clock domains in said circuit and user specified constraints; and
assigning each memory element to a group of memory elements of the same clock domain to be connected in a chain.

19. A method as defined in claim 13, said generating a scan chain specification including providing in said specification:
for each group of memory elements of the same clock domain to be connected in a chain, a group serial input port, a group serial output port, a list of memory elements to be included in said group; and
for each memory element, a serial input port, a serial output port, a scan enable port; a memory element type; and control signals.

20. A method as defined in claim 19, said generating a scan chain specification further including providing in said specification, for each memory element type, an equation describing the connection of the serial input port; and an equation describing the connection of the scan enable port.

21. A method as defined in claim 19, said generating a scan chain specification further including providing in said specification the identity of source and destination memory elements of paths between clock domains and associating each source and destination memory element with a capture disable group, and, for each capture disable group, a combination of memory elements making the capture disable inactive; and control signals for controlling the capture of said source and destination memory elements.

22. A method as defined in claim 19, said generating a scan chain specification further including providing in said specification, for each test point, information for guiding a test point insertion tool, including controllability and observability values of signals that are identifiable in both the RTL and gate-level descriptions, the values being input and output signals of a module or process to contain the test point.

23. A method as defined in claim 6, further including generating test logic compatible with said scan chain specification and inserting said test logic into said modified RTL circuit description.

24. A computer readable storage medium on which is embedded one or more computer programs, said one or more computer programs of designing a scan testable integrated circuit with embedded test structures for performing scan tests of said circuit, said one or more computer programs comprising a set of instructions for:
determining whether a circuit design meets predetermined embedded test requirements, the location at which test points and dedicated isolation cells will be inserted in the circuit and extracting all pertinent design information from a RTL circuit description that will be required to generate to insert embedded test objects into the RTL circuit description and a scan chain specification file for use in inserting scan chains and test points in a circuit netlist;
planning a test object insertion process and generating a test object environment in which descriptions and details of the generated test objects will be stored;
performing the test object insertion into a modified circuit RTL in which in lower physical regions or cores of the circuit, test objects are inserted into said circuit RTL, scan ports are provided for each core in the circuit, and RTL test points and any dedicated isolation cells are inserted into the circuit, and at the circuit top level, top level test objects are inserted into the circuit RTL, early verification of the embedded test objects in the design is performed and a modified RTL circuit description which is generated for synthesis by a synthesis tool into a circuit netlist;
generating and inserting scan chains and test points into the gate-level description.

25. A computer readable storage medium on which is embedded one or more computer programs, said one or more computer programs of designing a scan testable integrated circuit with embedded test structures for performing scan tests of said circuit, said one or more computer programs comprising a set of instructions for:
compiling a register-transfer level (RTL) circuit description of said circuit into an unmapped circuit description;
extracting information from said unmapped circuit description for use in generating and inserting RTL descriptions of test objects into said RTL circuit description and for use in generating and inserting scan chains into said circuit;
generating and inserting said RTL descriptions of said test objects into said RTL circuit description to produce a modified RTL circuit description;
storing said modified RTL circuit description;
synthesizing said modified RTL description into a gate level circuit description of said circuit; and
constructing and inserting scan chains into said gate level circuit description according to information extracted from said unmapped circuit description.

26. A computer readable storage medium as defined in claim 25, said constructing and inserting scan chains further including generating a final gate level circuit description.

27. A computer readable storage medium as defined in claim 25, said constructing and inserting scan chains further including analyzing said gate level circuit description and said information for use in generating scan chains, generating Tool Command Language (TCL) scripts to cause a design tool to transform functional memory elements into scannable memory elements and generate a final gate level circuit description.

28. A computer readable storage medium as defined in claim 25, said constructing and inserting scan chains further including analyzing said gate level circuit description and said information for use in generating scan chains, generating a modified gate level circuit description, and generating Tool Command Language (TCL) scripts to cause a design tool to substitute said modified gate level circuit description for said gate level circuit description.

29. A computer readable storage medium as defined in claim 25, said generating and inserting said RTL descriptions including generating and inserting scan ports and test ports to modules whose footprint needs to be preserved.

30. A computer readable storage medium as defined in claim 25, said information comprising clock domains in said circuit, identity and number of memory elements in each clock domain, interaction between memory elements of different clock domains, and controllability and observability of all nodes in the circuit.

31. A computer readable storage medium as defined in claim 25, further including, verifying that said RTL circuit description satisfies predetermined scan design rules.

32. A computer readable storage medium as defined in claim 25, said test objects including one or more of test controllers, clock controllers and test access ports, scan control signal generators.

33. A computer readable storage medium as defined in claim 32, said test objects further including test points providing isolation from uncontrollable logic.

34. A computer readable storage medium as defined in claim 32, said test objects further including test points providing isolation of modules to be tested independently of the rest of the circuit in a hierarchical scan test.

35. A computer readable storage medium as defined in claim 32, said test objects further including test points increasing the testability of circuit nodes with low controllability and/or observability.

36. A computer readable storage medium as defined in claim 32, said test controllers including ATPG compressors and decompressors and BIST controllers.

37. A computer readable storage medium as defined in claim 25, further including generating a scan chain specification that describes scan chain requirements for said circuit from extracted information for use in generating and inserting scan chains into said circuit.

38. A computer readable storage medium as defined in claim 25, said compiling a RTL circuit description of said circuit including partially synthesizing said RTL circuit description to generate said unmapped circuit description in which memory elements are inferred and distinguishable from combinational logic.

39. A computer readable storage medium as defined in claim 25, said compiling a RTL circuit description of said circuit and said generating and inserting said RTL descriptions of test objects further including utilizing user specified constraints information including maximum number of scan chains and/or maximum scan chain length, frequency of clock domains, identification of non-scannable portions of the circuit, and identification of cores in a hierarchical test approach.

40. A computer readable storage medium as defined in claim 25, said extracting information further including one or more of determining the location of test points, identifying and counting memory elements, identifying the clock domain associated with each memory element.

41. A computer readable storage medium as defined in claim 40, further including associating each source and destination memory element with a respective capture disable group.

42. A computer readable storage medium as defined in claim 40, said extracting information further including determining the number of scan chains based on the number of clock domains in said circuit and user specified constraints; and
assigning each memory element to a group of memory elements of the same clock domain to be connected in a chain.

43. A computer readable storage medium as defined in claim 37, said generating a scan chain specification including providing in said specification:
for each group of memory elements of the same clock domain to be connected in a chain, a group serial input port, a group serial output port, a list of memory elements to be included in said group; and
for each memory element, a serial input port, a serial output port, a scan enable port; a memory element type; and control signals.

44. A computer readable storage medium as defined in claim 43, said generating a scan chain specification further including providing in said specification, for each memory element type, an equation describing the connection of the serial input port; and an equation describing the connection of the scan enable port.

45. A computer readable storage medium as defined in claim 43, said generating a scan chain specification further including providing in said specification the identity of source and destination memory elements of paths between clock domains and associating each source and destination memory element with a capture disable group, and, for each capture disable group, a combination of memory elements making the capture disable inactive; and control signals for controlling the capture of said source and destination memory elements.

46. A computer readable storage medium as defined in claim 43, said generating a scan chain specification further including providing in said specification, for each test point, information for guiding a test point insertion tool, including controllability and observability values of signals that are identifiable in both the RTL and gate-level descriptions, the values being input and output signals of a module or process to contain the test point.

47. A computer readable storage medium as defined in claim 30, further including generating test logic compatible with said scan chain specification and inserting said test logic into said modified RTL circuit description.
